(19) United States
(12) Patent Application Publication
(10) Pub. No.: US 2026/0322216 A1
(43) Pub. Date: Oct. 15, 2026

(54) ELECTRIC MACHINE COOLING SYSTEM

(71) Applicant: FLUXWORKS, INC., Conroe, TX (US)

(72) Inventors: Becky Sue Morris, Canton, MI (US); Bryton Praslicka, Houston, TX (US); Christopher Luke Gomez, Montgomery, TX (US)

(21) Appl. No.: 19/701,555

(22) Filed: Jun. 8, 2026

Related U.S. Application Data
(63) Continuation of application No. PCT/US2024/059410, filed on Dec. 10, 2024.
(60) Provisional application No. 63/608,759, filed on Dec. 11, 2023.

(51) Int. Cl. H02K 9/19; H02K 1/16; H02K 1/17; H02K 1/278; H02K 7/00

(52) U.S. Cl. CPC H02K 9/19; H02K 1/165; H02K 1/17; H02K 1/278; H02K 7/003

(57) ABSTRACT

An electric machine is disclosed. The electric machine can include an inner rotor having a plurality of magnets, a modulator having a plurality of flow paths and at least partially surrounding the inner rotor, and a stator at least partially surrounding the modulator. During operation of the electric machine, the plurality of flow paths can convey a flow of a cooling liquid through the inner rotor, the modulator, or the stator. The modulator can include a plurality of ferromagnetic pieces and a holder. The plurality of flow paths can be located within the plurality of ferromagnetic pieces and/or within the holder. The plurality of flow paths can include a plurality of outward outlets configured to deliver flow to a first gap radially outward of the modulator or a plurality of inward outlets configured to deliver flow to a second gap radially inward of the modulator.

### RELATED APPLICATIONS

This application is a continuation of International Application No. PCT/US2024/059410, filed Dec. 10, 2024, which claims the priority benefit of U.S. Provisional Patent Application 63/608,759 filed on Dec. 11, 2023, entitled “ELECTRIC MACHINE COOLING SYSTEM,” which is incorporated by reference herein in its entirety.

### BACKGROUND

### Field

This disclosure relates to cooling an electric machine. In particular, some implementations are directed to methods and structures for an electric machine having a plurality of flow paths for cooling during operation.

### Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Electric machines generate heat during operation, and that heat leads to a decrease in electromagnetic performance. As such, there is a need to cool electric machines during operation, and more specifically, a need to efficiently and directly cool components of an electric machine during operation.

### SUMMARY

For purposes of summarizing the disclosure and the advantages achieved over the prior art, certain objects and advantages of the disclosure are described herein. Not all such objects or advantages may be achieved in any particular implementation. Thus, for example, those skilled in the art will recognize that the devices, systems, and methods may be embodied or carried out in a manner that achieves or optimizes one advantage or group of advantages as taught herein without necessarily achieving other objects or advantages as may be taught or suggested herein.

All of these implementations are intended to be within the scope of the devices, systems, and methods herein disclosed. These and other implementations will become readily apparent to those skilled in the art from the following detailed description of the implementations having reference to the attached figures, the devices, systems, and methods not being limited to any particular implementations disclosed.

In some implementations, an electric machine can include: an inner rotor including a plurality of magnets; a modulator including a plurality of flow paths and at least partially surrounding the inner rotor; and a stator at least partially surrounding the modulator; wherein, during operation of the electric machine, the plurality of flow paths conveys a flow of a cooling liquid through the inner rotor, the modulator, or the stator.

In some implementations, the modulator includes a plurality of ferromagnetic pieces and a holder. In some implementations, the plurality of flow paths are located within the plurality of ferromagnetic pieces. In some implementations, the plurality of flow paths are located within the holder. In some implementations, the plurality of flow paths are parallel to an axis of operation. In some implementations, the plurality of flow paths include a plurality of outlets within the electric machine. In some implementations, the plurality of flow paths include a plurality of outward outlets configured to deliver flow to a first gap radially outward of the modulator or a plurality of inward outlets configured to deliver flow to a second gap radially inward of the modulator.

In some implementations, the plurality of flow paths includes a plurality of outward outlets configured to deliver flow to a first gap radially outward of the modulator and a plurality of inward outlets configured to deliver flow to a second gap radially inward of the modulator, and the plurality of outward outlets are offset from the plurality of inward outlets. In some implementations, the electric machine includes a first set of distribution paths that extend radially outward and are configured to facilitate a flow to the plurality of flow paths. In some implementations, the inner rotor further includes a hollow shaft, and the hollow shaft is configured to facilitate a flow to the first set of distribution paths.

In some implementations, an electric machine can include: an inner rotor; a modulator that at least partially surrounds the inner rotor; and an outer component set that at least partially surrounds the modulator, the outer component set including: a stator including a plurality of slots facing the modulator; a plurality of windings located within the plurality of slots; a plurality of magnets located on an inner side of the stator; and a plurality of slot gaps at least partially defined by the plurality of magnets, the plurality of slots, and the plurality of windings.

In some implementations, the plurality of windings include a winding coating. In some implementations, the plurality of slot gaps include a slot gap coating. In some implementations, a fluid within the plurality of slot gaps directly contacts the plurality of magnets and the plurality of windings, and wherein the plurality of windings include a winding coating.

In some implementations, the electric machine includes a first set of distribution paths that extend radially outward and are configured to deliver a flow to the plurality of slot gaps. In some implementations, the modulator includes a plurality of flow paths. In some implementations, the plurality of flow paths include a plurality of outlets. In some implementations, the plurality of outlets facilitate flow to a first gap between the modulator and the inner rotor or a second gap between the modulator and the outer component set.

In some implementations, an electric machine can include: an inner rotor; and a stator that at least partially surrounds the inner rotor, the stator including: a plurality of slots spaced around an inner circumference of the stator; and a plurality of windings located within the plurality of slots; wherein a winding of the plurality of windings includes a fluid passage. In some implementations, the plurality of windings are hollow windings, and wherein the fluid passage is a plurality of fluid passageways located within the hollow windings.

In some implementations, an electric machine can include: an inner rotor; and a stator that at least partially surrounds the inner rotor, the stator including: a plurality of slots spaced around an inner circumference of the stator; a plurality of windings at least partially located within the plurality of slots; and a plurality of clips configured to secure the plurality of windings within the plurality of slots.

In some implementations, the plurality of windings have a length, the length being parallel to an operational axis and defined by a portion of the plurality of windings located within the plurality of slots. In some implementations, the plurality of clips have a clip depth, the clip depth being parallel to the operational axis, and the clip depth is less than the length of the plurality of windings. In some implementations, a first individual clip and a second individual clip of the plurality of clips are located within an individual slot of the plurality of slots, the first individual clip is located on a first side of the individual slot and the second individual clip is located on a second side of the individual slot, and the first side is opposite of the second side. In some implementations, the plurality of clips includes a backbone section connecting the plurality of clips.

In some implementations, an axial flux magnetically geared machine can include: a first magnetic rotor; a second magnetic rotor maintained in a spaced relationship from the first magnetic rotor; a modulator rotor disposed between the first magnetic rotor and the second magnetic rotor, the modulator rotor configured to modulate a magnetic field, wherein the modulator rotor includes a plurality of ferromagnetic pieces and a holder.

In some implementations, the plurality of flow paths are located within the plurality of ferromagnetic pieces. In some implementations, the plurality of flow paths are located within the holder. In some implementations, the plurality of flow paths are parallel to an axis of operation. In some implementations, the plurality of flow paths includes a plurality of outlets within the axial flux magnetically geared machine. In some implementations, the plurality of flow paths include a plurality of outward outlets configured with an inlet and an outlet to connect to a heat exchanger. In some implementations, the plurality of flow paths are contained in a closed-loop cooling jacket housing disposed about the outer circumference of the axial flux magnetically geared machine.

In some implementations, an axial flux magnetically geared machine can include: a first magnetic rotor; a second magnetic rotor maintained in a spaced relationship from the first magnetic rotor; a plurality of heat pipes that extend at least partially beyond the second rotor; and a modulator rotor disposed between the first magnetic rotor and the second magnetic rotor, the modulator rotor configured to modulate a magnetic field of at least one of the first magnetic rotor and the second magnetic rotor.

In some implementations, the plurality of heat pipes include a closed loop path connecting a first stationary housing of the first magnetic rotor and a second stationary housing of the second magnetic rotor. In some implementations, the plurality of heat pipes include a closed loop path connecting a first stationary housing of the first magnetic rotor and a second stationary housing of the second magnetic rotor, and a third stationary housing of the modulator rotor. In some implementations, the plurality of heat pipes at least partially extend beyond an output shaft of the second magnetic rotor, the plurality of heat pipes for convection cooling and are embedded into a back iron assembly of the second rotor, wherein, during operation of the axial flux magnetically geared machine, the plurality of heat pipes rotates with the second magnetic rotor and provides additional convection cooling of the second magnetic rotor. In some implementations, the heat pipes extend beyond the output shaft for convection cooling and are built into the magnet retention assembly of the low-speed rotor wherein, during operation of the axial flux magnetically geared machine, the plurality of heat pipes rotates with the machine providing additional convection cooling of the low-speed rotor.

In some implementations, an axial flux magnetically geared machine can include: a first magnetic rotor; a second magnetic rotor maintained in a spaced relationship from the first magnetic rotor; a modulator rotor disposed between the first magnetic rotor and the second magnetic rotor, the modulator rotor configured to modulate a magnetic field of at least one of the first magnetic rotor and the second magnetic rotor; and an integrated fan mechanically coupled to at least one of the first magnetic rotor or the second magnetic rotor; wherein, during operation of the axial flux magnetically geared machine, the integrated fan rotates forcing additional convection across the axial flux magnetically geared machine for cooling at least one of either the first magnetic rotor or the second magnetic rotor.

In some implementations, the second magnetic rotor maintained in a spaced relationship from the first magnetic rotor includes a plurality of heat pipes that extend at least partially beyond the second magnetic rotor. In some implementations, a stationary housing of at least one of the first magnetic rotor or the second magnetic rotor includes a heat sink.

### BRIEF DESCRIPTION OF THE DRAWINGS

These and other features, aspects, and advantages of the disclosure are described with reference to drawings of certain implementations, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1 illustrates an exploded view of an example electric machine.

FIG. 2 illustrates a cutaway front view of an example electric machine.

FIG. 3A illustrates a cutaway front view of an implementation of a portion of an example electric machine.

FIG. 3B illustrates a cutaway front view of an implementation of a portion of an example electric machine.

FIG. 3C illustrates a cutaway front view of an implementation of a portion of an example electric machine.

FIG. 3D illustrates a cutaway front view of an implementation of a portion of an example electric machine.

FIG. 4 illustrates a cutaway side view of an implementation of an example electric machine.

FIG. 5 illustrates a cutaway side view of an implementation of an electric machine.

FIG. 6 illustrates a cutaway side view of an implementation of an electric machine.

FIG. 7 illustrates a front view of an implementation of an example electric machine.

FIG. 8 illustrates a front view of an implementation of an example electric machine.

FIG. 9 illustrates a cutaway front view of an implementation of a portion of an example electric machine.

FIG. 10 illustrates a view of an implementation of a winding slot portion of an example electric machine.

FIG. 11 illustrates a view of an implementation of a winding slot portion of an example electric machine.

FIG. 12 illustrates a view of an implementation of a winding slot portion of an example electric machine.

FIG. 13 illustrates a side view of the winding slot of the example electric machine shown in FIG. 12.

FIG. 14 illustrates an isometric view of an example axial flux coaxial magnetic gear.

FIG. 15 illustrates a view of an implementation of the axial flux coaxial magnetic gear in which one rotor has heat sink fins affixed to the housing of the gearbox.

FIG. 16 illustrates an implementation of the axial flux coaxial magnetic gear in FIG. 15 in which an example fan or blower propeller for cooling is shown.

FIG. 17 illustrates a block diagram depicting an example thermal management system for the example axial flux coaxial magnetic gear of FIG. 14.

FIG. 18 illustrates a liquid cooled system that would implement cooling channels and/or tubing within the axial flux coaxial magnetic gear to circulate some form of cooling solution to remove heat from critical areas.

FIG. 19 illustrates an example of how a cooling inlet and outlet and the cooling jacket in FIG. 18 could be implemented in the stationary outer housing about the rotating part of the gear.

FIG. 20 illustrates an example implementation of heat pipes through the stationary parts of the axial flux coaxial magnetic gear.

FIG. 21 illustrates an implementation of the axial flux coaxial magnetic gear in FIG. 20 in which an example fan or blower propeller for cooling is shown.

FIG. 22 illustrates an implementation of the modulator rotor body inside of a modulator rotor housing with an example coolant implementation.

FIG. 23 illustrates an example magnetic gearbox assembly with housing where the heat pipes are integrated into the rotating parts of the axial flux coaxial magnetic gear.

FIG. 24 illustrates an example implementation of the axial flux coaxial magnetic gear in FIG. 20 with heat pipes having a larger surface area.

### DETAILED DESCRIPTION

Although several implementations, examples, and illustrations are disclosed below, it will be understood by those of ordinary skill in the art that the devices, systems, and methods described herein extend beyond the specifically disclosed implementations, examples, and illustrations and include other uses of the devices, systems, and methods and obvious modifications and equivalents thereof. Implementations are described with reference to the accompanying figures, wherein like numerals refer to like elements throughout. The terminology used in the description presented herein is not intended to be interpreted in any limited or restrictive manner simply because it is being used in conjunction with a detailed description of some specific implementations of the devices, systems, and methods. In addition, implementations can comprise several novel features. No single feature is solely responsible for its desirable attributes or is essential to practicing the devices, systems, and methods herein described.

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of implementations.

The present disclosure relates to a cooling system for an electric machine. The electric machine can be a motor or a generator. An electric machine can comprise a high-speed rotor and a low-speed rotor. The electric machine also includes a plurality of windings, a stator, a first set of magnets, a second set of magnets, and a modulator. Together these components allow the windings to drive or generate electricity via a high-speed rotor or a low-speed rotor. The cooling system can be integrated into the electric machine, so as to cool various components within the electric machine during operation. The cooling system can comprise cooling tubes, gaps, and passages that are in proximity to certain components of the electric machine.

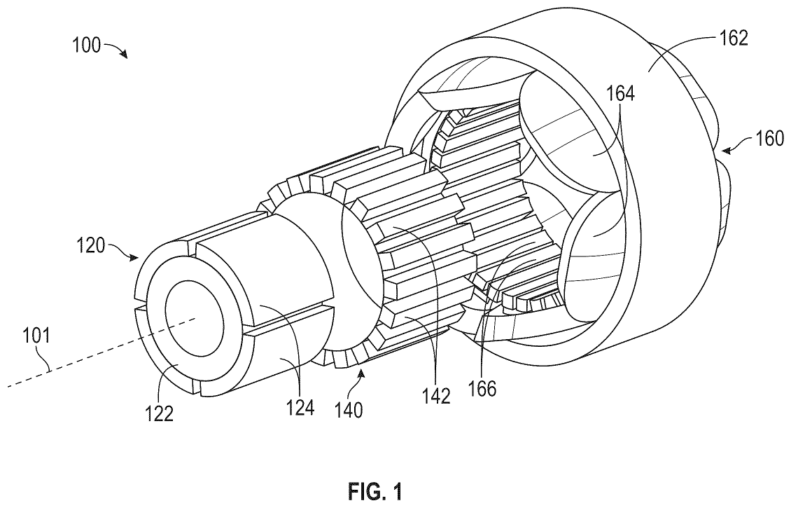

FIG. 1 is a view of an electric machine 100. An electric machine 100 can combine the benefits of an electric motor and an electric gear, putting both in a single package. This can allow a lower speed, higher torque output than traditional electric motors. The electric machine 100 comprises a high-speed inner rotor 120, a low-speed rotor 140, an outer set of components 160, and an operation axis 101. The high-speed inner rotor 120 and the low-speed rotor 140 both can rotate about the operation axis 101. The fixed outer set of components 160 can comprise an outer stator 162, a plurality of windings 164, and an outer set of magnets 166. The outer stator 162, the plurality of windings 164, and the outer set of magnets 166 can be connected together or fixed in relation to each other. The outer set of components 160 can be stationary during operation of the electric machine 100.

The inner rotor 120 can comprise a shaft 122 and an inner set of magnets 124. The shaft 122 can be hollow as shown, or it can be solid. Further, the shaft 122 can connect to an output shaft or an input shaft, allowing the electric machine to receive or output power or a force. The low-speed rotor 140 or more specifically the modulator 142 can connect to an output shaft or an input shaft, allowing the electric machine to receive or output power or a force. The inner set of magnets 124 can be connected to the outside of the shaft 122. The low-speed rotor 140 can comprise a modulator 142. The high-speed inner rotor 120 can be located inside of the low-speed rotor 140, which can be located inside of the outer set of components 160. The electric machine, if operating as a motor, can be driven via the outer stator 162 and the plurality of windings 164. The outer stator 162 and the plurality of windings 164 can drive the high-speed inner rotor 120 at a high-speed. In turn, the high-speed inner rotor 120 can cooperate with the outer set of magnets 166 to drive the low-speed rotor 140, specifically driving the modulator 142. Modulator 142 can be made from a ferromagnetic material such as magnetic steel and can be comprised of a stack of magnetic steel laminations. The modulator 142 facilitates a connection between the outer set of magnets 166 and the inner set of magnets 124 to facilitate a geared interaction.

During operation of an electric machine 100, the electric machine 100 can generate heat, which can decrease the performance of the electric machine 100. The heat can be generated from multiple sources. Two sources of heat are due to electrical resistance and the change in magnetic fields resulting in hysteresis, eddy current, or excess loss. As such the plurality of windings 164, the outer set of magnets 166, the inner set of magnets 124, and the modulator 142 can generate heat during operation of the electric machine 100.

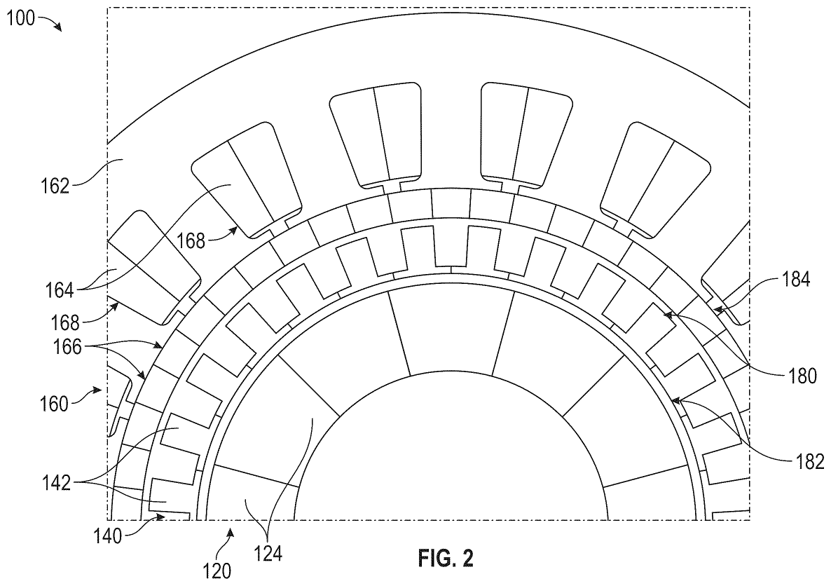

FIG. 2 is a view of an implementation of the electric machine 100. The electric machine 100 can comprise a first gap 180 located between the outer set of components 160 and the low-speed rotor 140. More specifically, the first gap can be between the modulator 142 and the outer set of magnets 166. The electric machine 100 can further comprise a second gap 182 between the low-speed rotor 140 and the high-speed inner rotor 120. More specifically, the second gap 182 can be between the modulator 142 and the inner set of magnets 124.

The stator 162 can comprise a plurality of slots 168. The plurality of slots 168 can be configured to hold the plurality of windings 164. The plurality of slots 168 can be circumferentially spaced around the stator 162. The plurality of slots 168 can be located on an inside circumference of the outer stator 162. The plurality of slots 168 can have a slot opening on the interior of the stator 162, such that the slot faces the center of the electric machine 100. The plurality of windings 164 can be located within the plurality of slots 168. The electric machine 100 can further comprise a slot gap 184 located between the plurality of windings 164 and the outer set of magnets 166. Although not shown, the slot gap can comprise a slot liner and/or a varnish against the windings 164, as such the slot gap 184 can be located between the liner or varnish and the outer set of magnets 166. The slot gap 184 can be defined by the portion of the slot 168 that is not occupied by the plurality of windings 164. Fluid can be driven through or along the slot gap 184, the second gap 182, or the first gap 180 during operation to cool components of the electric machine 100. The fluid can be a liquid or a gas. The liquid can be a traditional coolant, air, oil/transmission fluid, or a water ethylene glycol mixture.

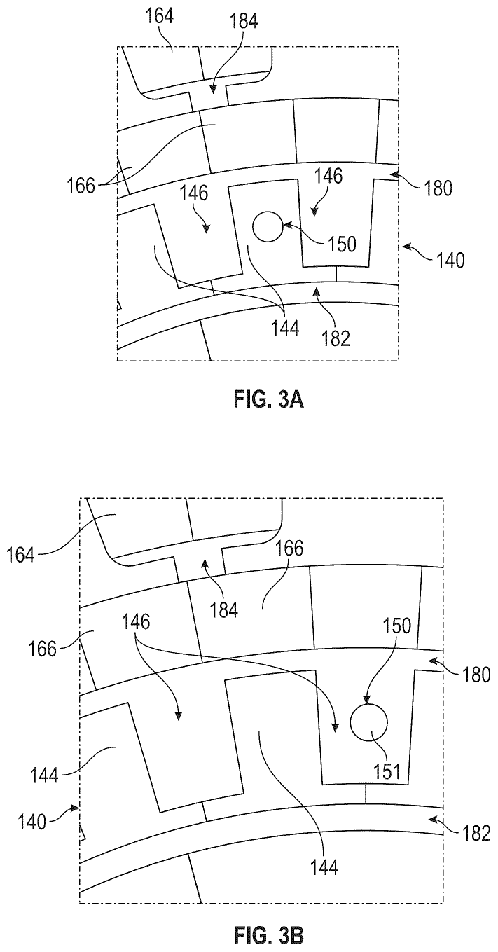

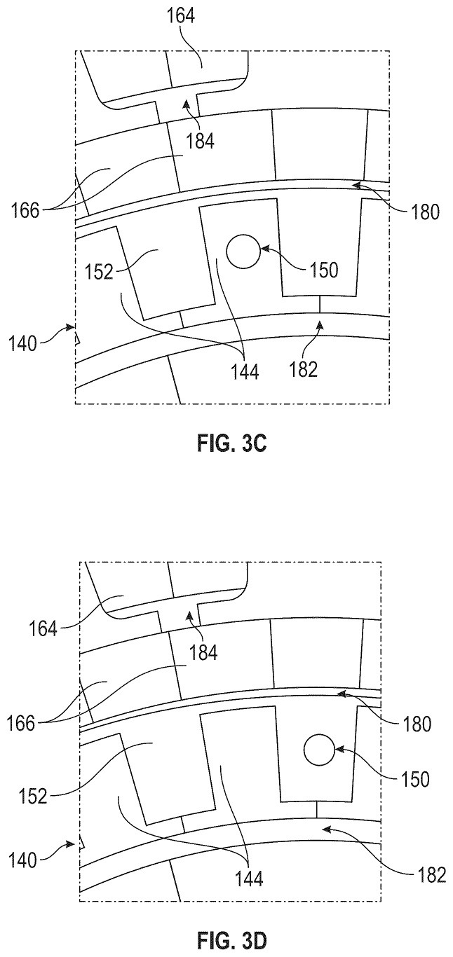

FIG. 3A is a detailed view of the low-speed rotor 140. The low-speed rotor 140 comprises the modulator 142. The modulator 142 comprises a plurality of ferromagnetic pieces 144. The plurality of ferromagnetic pieces 144 can be a single piece with a plurality of ferromagnetic sections. As such, it should be understood that the plurality of ferromagnetic pieces 144 can also refer to a plurality of ferromagnetic sections. The plurality of ferromagnetic pieces 144 can be spaced out within the low-speed rotor 140. The plurality of ferromagnetic pieces 144 can be spaced out evenly, but they need not be. In between each individual ferromagnet of the plurality of ferromagnetic pieces 144, there can be a modulator gap 146. The modulator gap 146 can be an air gap, as shown in FIGS. 3A and 3B, or it can be filled by another component or material, as shown in FIGS. 3C and 3D. Individual ferromagnetic pieces 144 can comprise a primary flow path 150, as shown in FIG. 3A. It should be understood that all, some, or a single one of the individual ferromagnetic pieces 144 can comprise a primary flow path 150, such that the primary flow path 150 comprises at least one to a plurality of flow paths. The primary flow path 150 can comprise a lumen or channel that runs down a length of the modulator 142. The primary flow path 150 can be substantially parallel to the operational axis 101. The primary flow path 150 can be located in a center of the plurality of ferromagnetic pieces 144. The primary flow path 150 can be located closer to or farther from the operational axis 101, while still within the plurality of ferromagnetic pieces 144. The primary flow path 150 can also be located within the modulator gap 146, as shown in FIG. 3B. The primary flow path 150 can be a tube 151 within the modulator gap 146 (FIG. 3B), or the path 150 can be at least partially defined by the plurality of ferromagnetic pieces 144 (FIG. 3A). Fluid can be driven through or along the primary flow path 150 during operation to cool components of the electric machine 100. The fluid can be a liquid or a gas. The liquid can be any of the previously mentioned types.

FIG. 3C is a detailed view of an alternative implementation of the low-speed rotor 140. The low-speed rotor 140 can further comprise a holder 152. The holder 152 can be a nonmagnetic holder configured to hold the plurality of ferromagnetic pieces; it can also be a nonconductive material. The holder 152 can be made of a plurality of pieces or can be a single component. The holder 152 can be at least partially located within the modulator gap 146. The holder 152 can entirely or partially fill the modulator gap 146. The holder 152 can hold, support, secure, or fix the plurality of ferromagnetic pieces 144. The holder 152 can secure the plurality of ferromagnetic pieces 144 in relation to each other. Further, the holder 152 can fully or partially surround the plurality of ferromagnetic pieces 144. As shown in FIG. 3D, the primary flow path 150 can be located within the holder 152. It should be understood that the primary flow path 150 can be located within the plurality of ferromagnetic pieces 144 and the holder 152. By locating the flow path 150 within the plurality of ferromagnetic pieces 144 or the holder 152, this places the flow path in direct proximity to critical components that require cooling. Components, such as the modulator 142, the outer set of magnets 166, the inner set of magnets 124, and the plurality of windings 164, heat up during operation. As the components heat up, there can be a decrease in their magnetic strength and performance. As such, there is a need to cool the previously mentioned components. The primary flow path 150 is able to achieve the cooling of the previously mentioned components in order to maintain the performance of the electric machine.

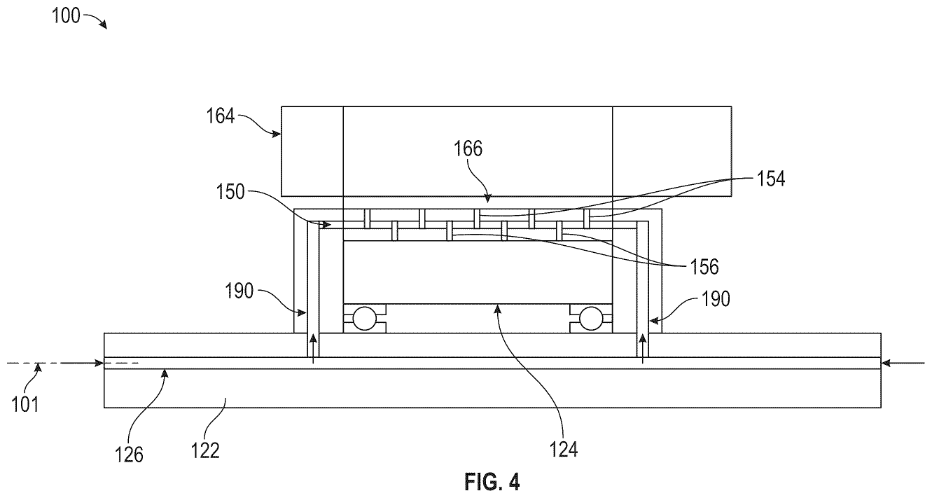

FIG. 4 is an implementation of the electric machine 100 in accordance with the present disclosure. The shaft 122 can comprise a shaft flow path 126 within the shaft 122. The shaft flow path 126 can be the entire length of the shaft 122 or can be only part of the length. The shaft 122 can be hollow, creating a void, which can define the shaft flow path 126. The electric machine 100 can further comprise a radial delivery flow path 190. The radial delivery flow path 190 can be connected to the shaft 122, such that the shaft flow path 126 is connected to the radial delivery flow path 190. The fluid can flow or be conducted through the shaft flow path 126 and into the radial delivery flow path 190.

The low-speed rotor 140 can further comprise a plurality of outward outlets 154 and a plurality of inward outlets 156. The plurality of outward outlets 154 and the plurality of inward outlets 156 can be connected to the primary flow path 150 and can allow flow into the interior space of the electric machine 100 to deliver the fluid, such as the first gap 180 and the second gap 182. The fluid within the interior space of the electric machine 100, including in the first gap 180 and the second gap 182, can fill any air gap within the electric machine 100. The plurality of outward outlets 154 and the plurality of inward outlets 156 can be located in the plurality of ferromagnetic pieces 144, the modulator gap 146, the holder 152, or any combination thereof. The fluid within the radial delivery flow path 190 can flow, or be conducted, into the primary flow path 150. The fluid within the primary flow path 150 can then be conducted or flow into the plurality of outward outlets 154 and the plurality of inward outlets 156. The fluid flow through the plurality of outward outlets 154 can flow into the first gap 180, and the fluid flowing through the plurality of inward outlets 156 can flow into the second gap 182. The fluid can flow through other gaps within the electric machine 100 and be collected. The collected fluid can then be pumped into the electric machine 100, or more particularly into the shaft 122.

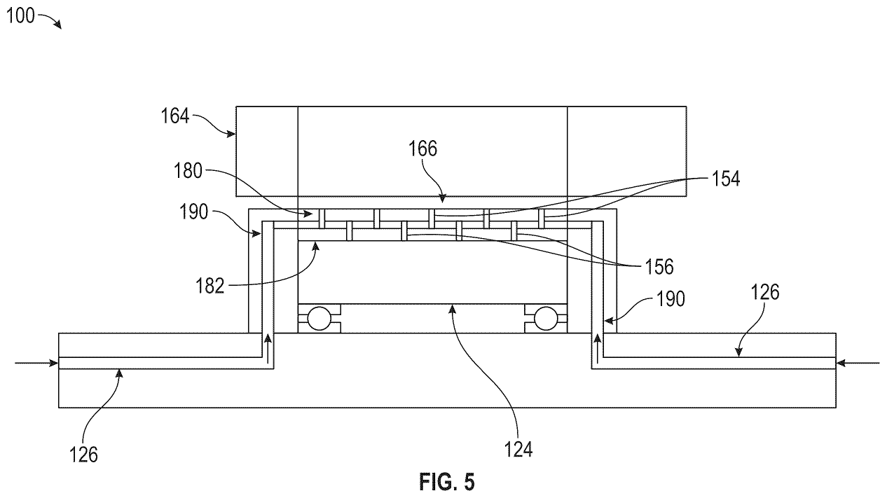

FIG. 5 is an alternative implementation of the electric machine 100 in accordance with the present disclosure. The shaft flow path 126 can be a partial length of the shaft 122 as shown in the present implementation. The shaft flow path 126 can be only as long as is necessary for the shaft flow path 126 to connect with the radial delivery flow path 190. This can reduce the amount of fluid required, it can generate a higher pressure or flow rate in other areas of the system, it can increase manufacturability, and/or it can increase the strength of the shaft.

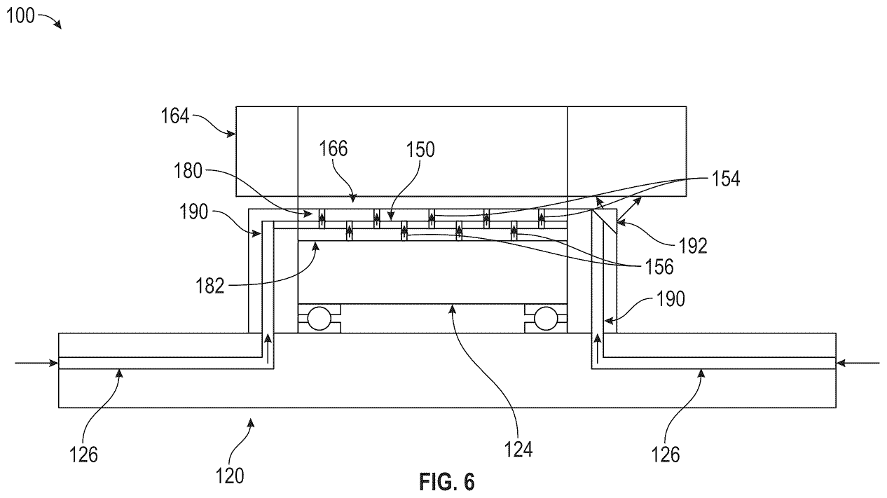

FIG. 6 is another alternative implementation of the electric machine 100 in accordance with the present disclosure. The electric machine 100 can further comprise a modulator delivery flow path exit 192. The modulator delivery flow path exit 192 can be a flow outlet that allows flow from the radial delivery flow path 190 to flow through the flow path exit 192 and onto the plurality of windings 164. In other implementations, the flow exiting the flow path exit 192 can flow into the interior spaces of the electric machine 100, such as the first gap 180 and the second gap 182. As shown in FIG. 6, one radial delivery flow path 190 can be connected to a side of the primary flow path 150, while another radial delivery flow path 190 can terminate with the modulator delivery flow path exit 192. The modulator delivery flow path exit 192 can be an additional outlet for a radial delivery flow path 190 that is connected to a primary flow path 150. Further, the radial delivery flow path 190 can be located on both sides of the electric machine 100, and there can be multiple radial delivery flow paths 190 on each side. Likewise, the number of combinations of connections between radial delivery flow path 190 and primary flow path 150 or modulator delivery flow path exit 192 can vary.

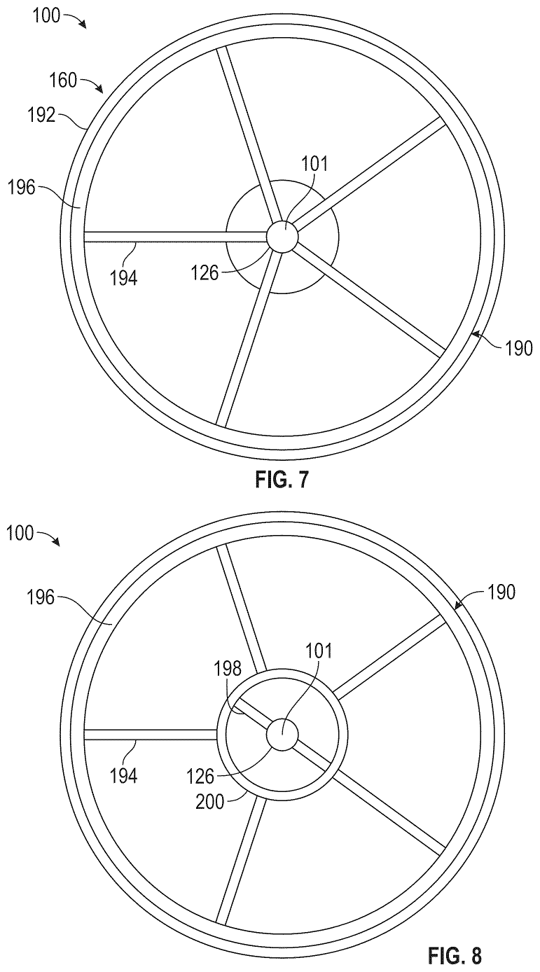

FIG. 7 is an implementation of the electric machine 100 in accordance with the present disclosure. The electric machine 100 can comprise a radial delivery flow path 190. The radial delivery flow path 190 can comprise a first set of distribution paths 194. The first set of distribution paths 194 can extend from a center of the electric machine 100 (e.g., the shaft flow path 126) to an outward portion of the electric machine 100, such as the area proximate to the outer set of components 160. The first set of distribution paths 194 can extend radially outward from the operational axis 101. The first set of distribution paths 194 can also connect to the primary flow path 150 (not shown) at a terminus of the first set of distribution paths 194 or along the length of the first set of distribution paths 194. The first set of distribution paths 194 can connect to an outer circular flow path 196. The first set of distribution paths 194 and the outer circular flow path 196 can be configured to cool an end portion of the electric machine 100 or deliver flow to paths parallel to the operational axis 101, such as the primary flow path 150.

FIG. 8 is an implementation of the electric machine 100 in accordance with the present disclosure. The electric machine 100, specifically the radial delivery flow path 190, can further comprise a second set of distribution paths 198 and an inner circular flow path 200. The second set of distribution paths 198 can extend from a center of the electric machine 100, such as the shaft flow path 126 to the inner circular flow path 200. The inner circular flow path 200 can also be connected to the first set of distribution paths 194. As such, a flow may be conveyed through shaft flow path 126, then through the second set of distribution paths 198, then through the inner circular flow path 200, then through the first set of distribution paths 194, and then into the outer circular flow path 196. The flow may be conducted through the primary flow path 150, the first gap 180, or the second gap 182 via any one of the radial delivery flow paths 190.

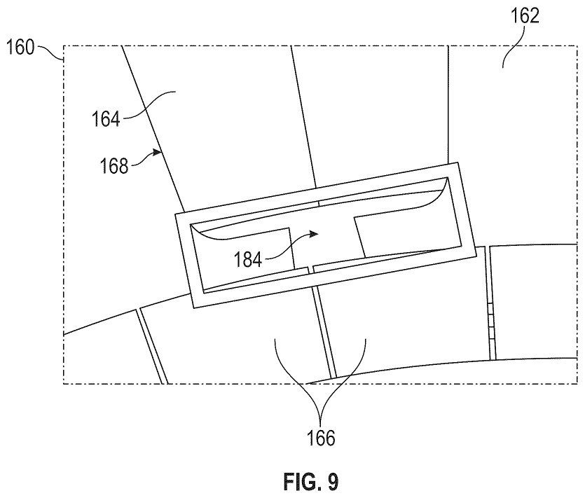

FIG. 9 is a detailed view of a section of the electric machine 100, specifically the outer set of components 160. The outer set of components 160 comprises the outer stator 162 with a plurality of slots 168 within the outer stator 162. The plurality of windings 164 can be located within the plurality of slots 168. The plurality of windings 164 may be secured within the plurality of slots 168 individually or as a pack. The plurality of windings 164 can be secured via compression, friction, an added material, a coating, or any other known method. The plurality of windings 164 can be coated by a winding coating prior to being inserted into the plurality of slots 168 or after they are disposed in the slots 168. The winding coating, which may be called a coating or an enamel, can be a thermoset polymer-based insulation layer, which can be employed when the winding comprises copper or aluminum magnet wire. The winding coating may also be thermoset materials such as polyurethane, polyamide, polyimide, or other similar materials. The plurality of windings 164 may not fill the entirety of the plurality of slots 168 as shown in the present implementation, resulting in a space between the plurality of slots 168 and the outer set of magnets 166. The gap defined by the plurality of slots 168, the plurality of windings 164, and the outer set of magnets 166 can serve as the slot gap 184. The slot gap 184 can allow a fluid flow to cool the outer stator 162, the plurality of windings 164, and the outer set of magnets 166. The inside of the slot gap 184 can be coated, filled, partially filled, or lined with a slot gap coating to prevent direct electric contact between the fluid and the outer stator 162, the plurality of windings 164, and the outer set of magnets 166, as such the fluid within the slot gap 184 may not directly contact the outer stator 162, the plurality of windings 164, and the outer set of magnets 166. The slot gap coating can be an epoxy resin, which can offer higher thermal conductivity. The slot gap coating could also be a varnish, which has a high dielectric strength. It should be understood that the slot gap coating could be any one of the materials described above, any of the materials described relating to the winding coating, or any other similar or commonly used material. In other implementations the outer stator 162, the plurality of windings 164, or the outer set of magnets 166 may have their own coating, barrier, or insulation to prevent direct contact or electrical contact with the fluid.

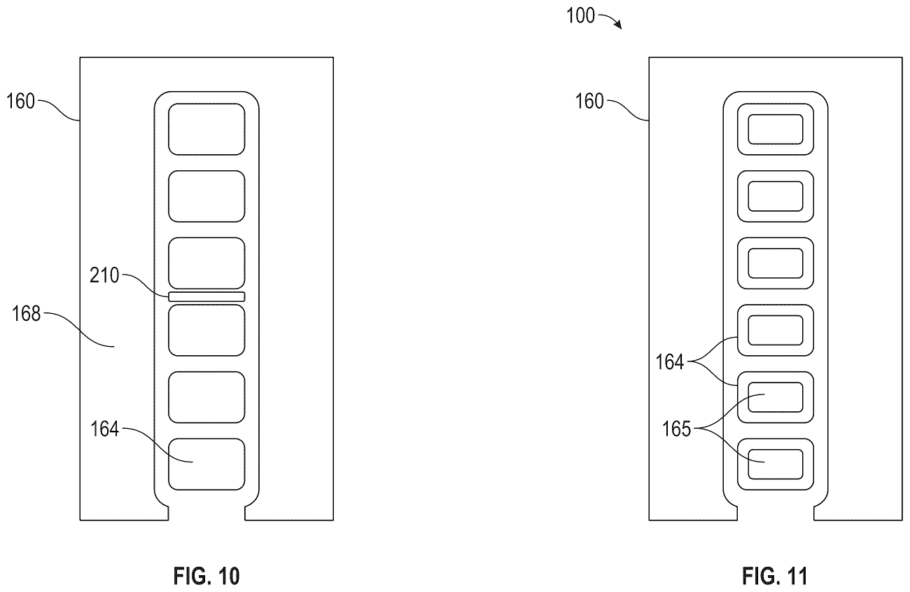

FIG. 10 is a detailed view of a section of the electric machine 100, specifically a portion of the outer set of components 160. The outer set of components 160 can further comprise a winding cooling tube 210. The plurality of windings 164, located within the plurality of slots 168, can have a winding cooling tube 210 located between individual windings of the plurality of windings 164. The winding cooling tube 210 can have a flow of coolant through it, allowing it to cool the plurality of windings 164. There can be a single or multiple winding cooling tubes 210 in each of the plurality of windings 164 located within an individual slot. The winding cooling tube 210 can also be used in conjunction with cooling via the slot gap 184.

FIG. 11 is a detailed view of a section of the electric machine 100, specifically a portion of the outer set of components 160. The plurality of windings 164 can be cooling windings comprising a hollow winding flow tube 165. The hollow winding flow tube 165 can be a flow path (e.g., a plurality of fluid passageways) located within the plurality of windings 164. The hollow winding flow tube 165 can facilitate the cooling of the plurality of windings 164 via the flow of coolant. In the present implementation, all of the plurality of windings 164 comprise a hollow winding flow tube 165; however, that need not be the case. A single individual winding of the plurality of windings 164 can comprise a hollow winding flow tube 165.

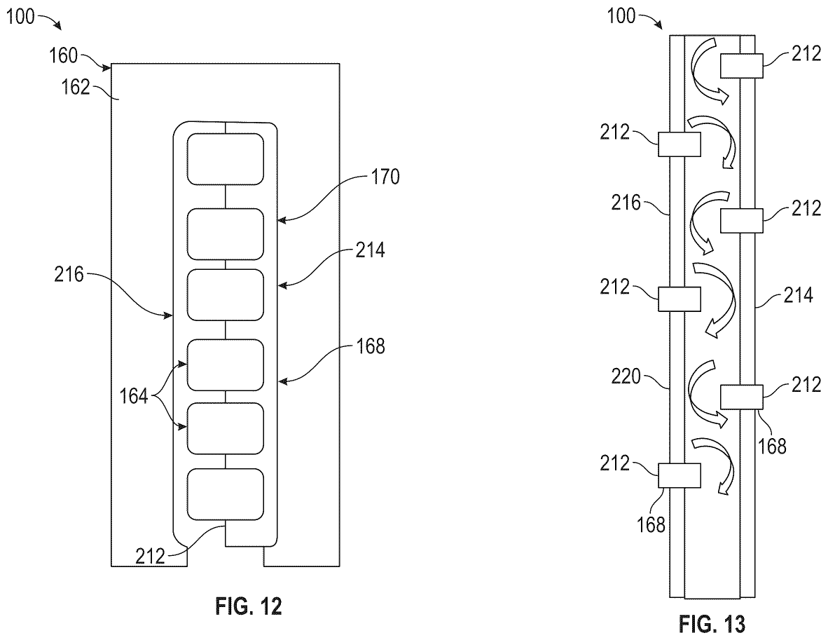

FIG. 12 is a detailed view of a section of the electric machine 100, specifically a portion of the outer set of components 160. The outer set of components 160 can comprise a plurality of winding clips 212. The plurality of winding clips 212 can hold, secure, or capture the plurality of windings 164 within the plurality of slots 168. An individual clip 212 of the plurality of winding clips 212 can be located on a single side of the slot 168. For example, the clip 212 can extend from a first side 214 of the slot wall 170 to a middle of the slot 168. The clip 212 can extend between 30% and 70% across the slot 168 from a first side 214 towards a second side 216, the second side 216 opposite from the first side 214, such that there is a gap on the second side 216 for fluid to flow through. The slot 168 can also extend from a second side 216 across the slot 168. The clip 212 can extend from a top of the slot 168 to a bottom, but it need not extend the full height of the slot 168. The clip 212 can be made out of an insulating material, such that direct contact with the plurality of windings 164 does not interfere with the operation of the electric machine 100.

FIG. 13 is an alternative angle of the electric machine 100 shown in FIG. 12. The slot of the plurality of slots 168 comprises a plurality of winding clips 212. The plurality of slots 168 can alternate between the first side 214 and the second side 216 such that the flow, as demonstrated by the arrows, can alternate back and forth. This can facilitate cooling the plurality of windings 164 and can improve performance by increasing the surface area of the plurality of windings 164 that the fluid contacts, increasing turbulence within the plurality of slots 168, and creating a more direct physical contact link between the windings and the slot 168 with a decreased thermal resistance. Although the present implementation shows a first side 214, second side 216, first side 214, second side 216 pattern for the clip locations, it should be understood that other patterns, such as two clips 212 on a first side 214, two clips 212 on a second side 216, two clips 212 on a first side 214, and two clips 212 on a second side 216, can be used. The clips 212 have a depth that is less than a length of the windings, so that multiple clips 212 and gaps can exist along the length of the winding. The clip 212 can also replace the use of a slot liner or varnish impregnating. One use of the slot liner can be to protect the winding coating from being scratched/damaged by the edge of the slot during the insertion and twisting process of the windings. The clips 212 can protect the windings during installation, for example, the clips 212 can stick out slightly from the ends of the core, and as such can protect the windings during the installation process. The plurality of winding clips 212 could also be a single piece. The single unit could comprise a plurality of clips 212 on a first side 214 and a second side 216, and a backbone section 220 connecting the plurality of clips. In this implementation, the windings can be inserted into the clip 212 ahead of time, and the assembly comprising the windings and the clips 212 could be inserted into the slot 168.

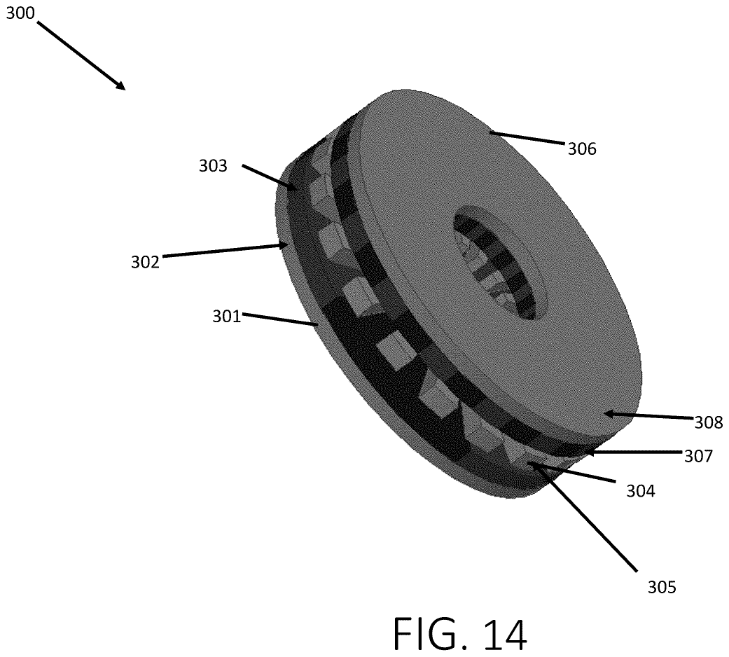

FIG. 14 is an isometric view of an axial flux coaxial magnetic gear 300. The axial flux magnetic gear 300 can include a first rotor 301 (e.g., a high-speed magnetic rotor) having a ferromagnetic steel such as a soft magnetic composite or a tape wound lamination, or a solid piece of electrical steel as a back iron yoke 302 and permanent magnets 303. The modulators 304 can enable the transmission of magnetic flux coupling internal and external mechanical systems without requiring physical contact and having different magnetic pole pairs. The modulators 304 can be made of a ferromagnetic material such as magnetic steel and can be comprised of a stack of magnetic steel laminations. The modulators 304 can modulate a magnetic field of at least one of an input element and/or an outer element. The modulators 304 can comprise a plurality of ferromagnetic pieces 305 (e.g., soft magnetic pole pieces). The plurality of ferromagnetic pieces can be a single piece with a plurality of ferromagnetic sections. As such, it should be understood that the plurality of ferromagnetic pieces can also refer to a plurality of ferromagnetic sections. The plurality of ferromagnetic pieces 305 can be spaced out within the soft magnetic pole pieces. The plurality of ferromagnetic pieces 305 can be spaced out evenly, but they need not be. In between each individual ferromagnet of the plurality of ferromagnetic pieces 305, there can be a modulator gap. The modulator gap can be an air gap or it can be filled by another component and/or material. The axial flux coaxial magnetic gear 300 can further comprise a second rotor 306 (e.g., a low-speed magnetic rotor) comprised of at least permanent magnets 307 and having a ferromagnetic steel such as a soft magnetic composite or a tape wound lamination, or a solid piece of electrical steel as a back iron yoke 308. The second rotor 306 can be positioned at a fixed distance from the first rotor 301, such that there is a gap between the first rotor 301 and the second rotor 306. The yoke 308 can have a through bore or may be a solid puck, and the second rotor 306 can be connected to a shaft, just as the first rotor 301 can be connected to a shaft.

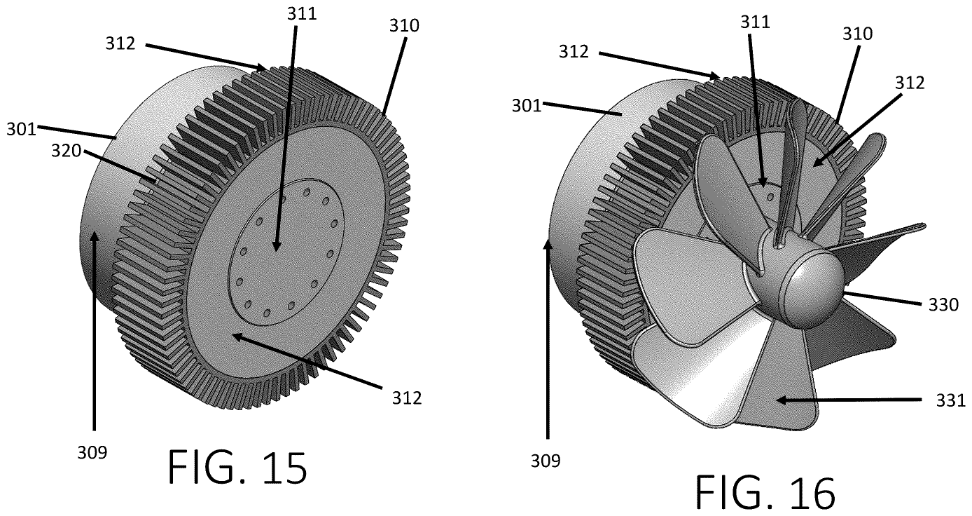

FIG. 15 depicts an alternative view of the axial flux magnetic gear 300 comprising at least a first rotor 301, second rotor 306, a stationary housing 309 about the first rotor 301, and a stationary housing 312 about the second rotor 306. In this implementation, an exemplary fin 310 comprised of a thermally conductive material, such as copper, aluminum, or cast iron, to increase surface area can act as a heat sink for increased thermal surface area for convection cooling of the axial flux coaxial magnetic gear 300. A second rotor shaft 311 (e.g., low speed rotor shaft) can be free to rotate inside the stationary housing 312 of the second rotor 306.

A modulating structure 320 can be disposed between the first rotor 301 and the second rotor 306 of the axial flux coaxial magnetic gear 300. The modulating structure 320 can modulate a magnetic field of at least one of the first rotor 301 and the second rotor 306.

FIG. 16 illustrates another view of the axial flux magnetic gear 300 comprising at least a first rotor 301, second rotor 306, a stationary housing 309 about the first rotor 301, and a stationary housing 312 about the second rotor 306. In this implementation, an exemplary fin 310 comprised of a thermally conductive material, such as copper, aluminum, or cast iron, to increase surface area can act as a heat sink for increased thermal surface area for convection cooling of the axial flux coaxial magnetic gear 300. The second rotor shaft 311 can be free to rotate inside the stationary housing 312 of the second rotor 306. In this arrangement, the axial flux coaxial magnetic gear 300 can also include a blower fan assembly 330 for cooling that can be mechanically affixed to the first rotor 301 (e.g., a high-speed rotor) and externally exited to force additional cooling across the fins 310 (e.g., heat sink). Connected to the axial flux coaxial magnetic gear 300 can be a fan balance 331, where each fan balance 331 is designed to force additional convection cooling.

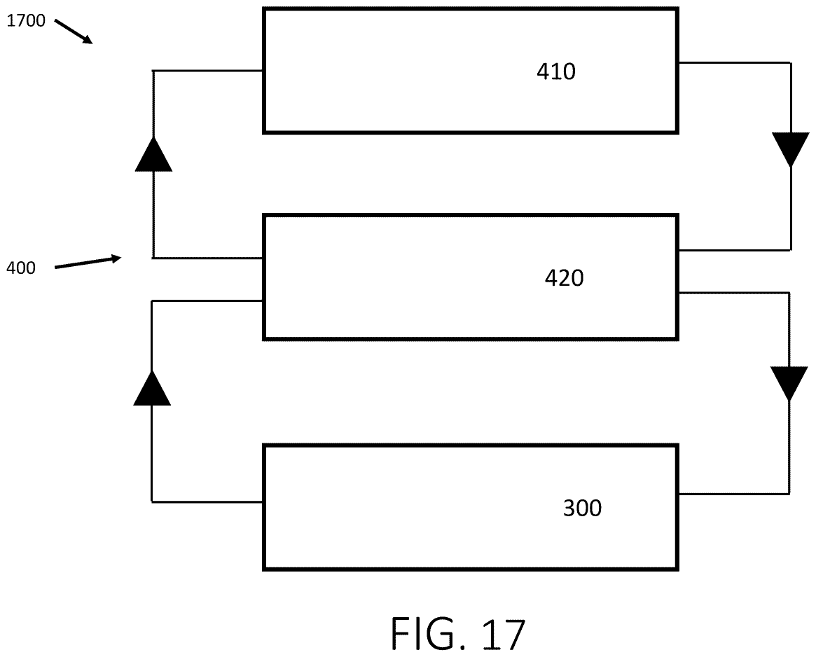

FIG. 17 depicts a functional block diagram 1700 of a liquid cooled system 400 to cool the axial flux coaxial magnetic gearbox 300. The liquid cooled system can include a heat exchanger 420 and a cooling system 410. The liquid cooled system 400 can be a closed loop, and liquid cooling is shown correspondingly as part of similar cooling techniques. A closed loop cooling system would be a self-contained style of cooling that can be used for areas having explosion proof ratings.

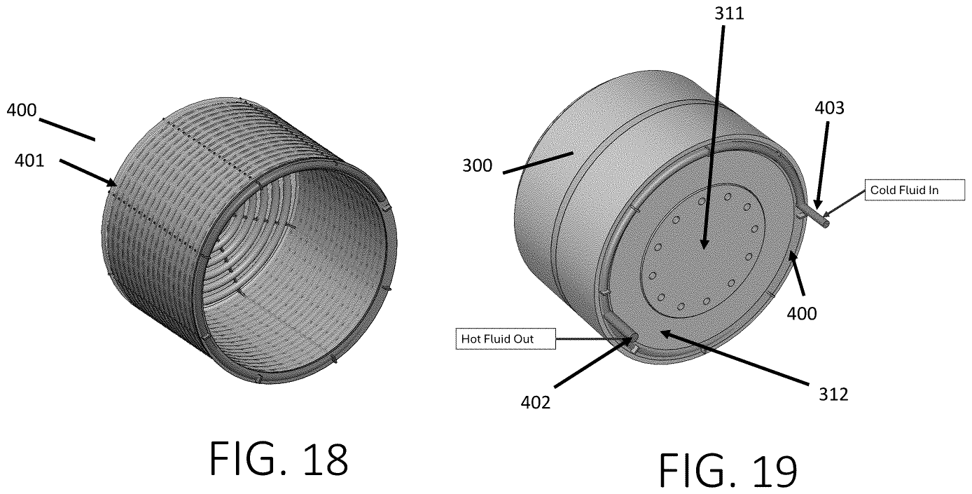

FIG. 18 depicts an example liquid cooling system 400 for a rotating device 401 including tubing 402 of a thermally conductive material, usually a copper or aluminum rigid tubing. The tubing 402 can be configured to transport coolant fluid in close proximity to any heat-generating components of the rotating device 401. This arrangement allows the tubing 402 to absorb and transfer heat away from the rotating device 401. The thermally conductive nature of the tubing 402 enhances the cooling performance by supplementing the fluid-based heat transfer with direct thermal conduction along the walls of the tubing 402. To accommodate the mechanical and thermal demands of the rotating device 401, the tubing 402 can be shaped or routed in one or more patterns that maximize contact with heat sources while maintaining a low-resistance fluid pathway. For example, the tubing 402 can include bends, coils, or flexible sections to address thermal expansion and mechanical movement associated with rotation. The liquid cooling system 400 can handle coolant flow facilitated by a pump, which ensures continuous circulation of the fluid through the tubing. The system 400 can also include additional thermal management components, such as heat sinks or radiators, to dissipate the extracted heat into the surrounding environment.

FIG. 19 depicts an example of the liquid cooled system 400 that can be employed in an example axial flux coaxial magnetic gearbox 300 with first rotating shaft 311 (e.g., an output shaft) depicted and stationary second rotor housing 312 (e.g., stationary low-speed rotor housing). Exemplary cooling outlets 402 and inlets 403 are depicted. The liquid cooled system 400 can be direction dependent and/or direction agnostic; however, an exemplary marking of one inlet 403 having cold fluid in and one outlet 402 having hot fluid out is depicted. The depiction should not be construed to suggest that the same inlet could not be used for cold and hot, and inlet and outlet being reversed is allowable.

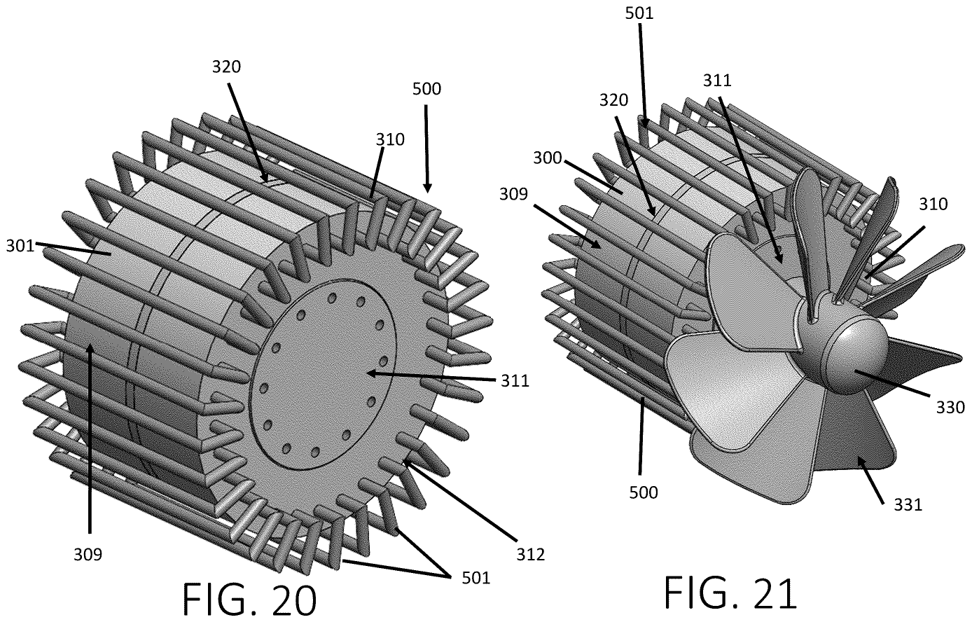

FIG. 20 depicts another view of the axial flux magnetic gear 300 comprising at least a first rotor 301, second rotor 306, a stationary housing 309 about the first rotor 301, and a stationary housing 312 about the second rotor 306. The first rotor 301 inside stationary housing 309 can include heat pipes 500 being connected and running through at least a portion of the axial flux coaxial magnetic gear 300 (e.g., either some or all of the entire gearbox assembly) and connecting also to the stationary housing 312 of the low-speed rotor subassembly 310. The heat pipes 500 can run through the modulator rotor subassembly 312 but need not. Each individual heat pipe 501 flows heat to increase the convection cooling capability of the assembly of the axial flux coaxial magnetic gear 300.

FIG. 21 depicts a variant of FIG. 20 with first rotor 301 inside the stationary housing 309 and having heat pipes 500 being connected and running through at least a portion of or the entire axial flux coaxial magnetic gear 300 and connecting also to the stationary housing 312 of the second rotor 306. The heat pipes 500 can run through the modulator rotor subassembly 320 but need not. Each individual heat pipe 501 can flow heat away from the heat-generating components to increase the convection cooling capability of the axial flux coaxial magnetic gear 300. An additional blower fan assembly 330 is connected, where each fan balance 331 is designed to force additional convection cooling.

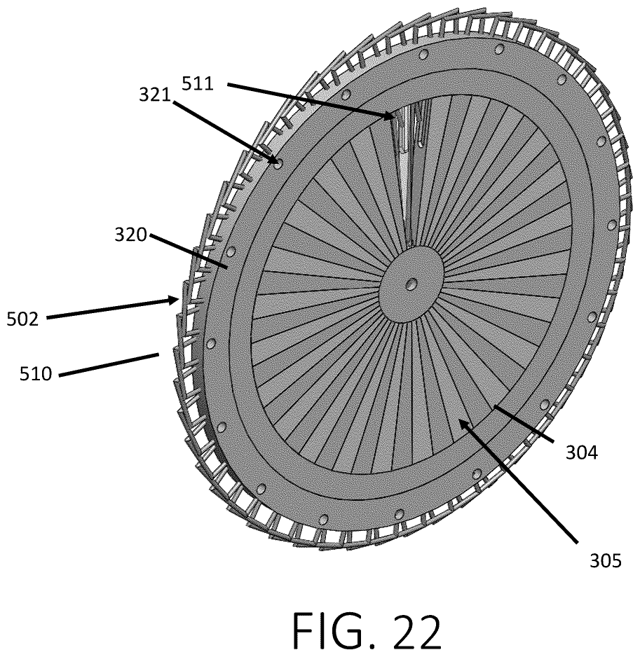

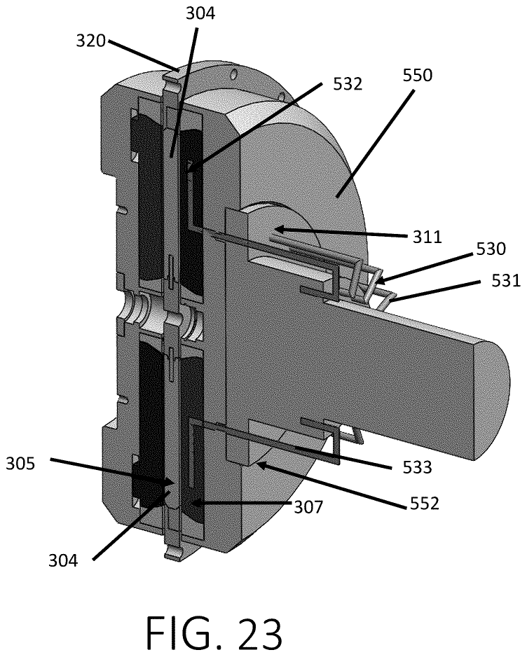

FIG. 22 depicts a modulator rotor subassembly 320 with modulator subassembly through holes 321 for affixing the device to the axial flux coaxial magnetic gear 300. Each modulator 304 can include a heat pipe 511 inside or affixed to a soft magnetic pole piece (e.g., a plurality of ferromagnetic pieces 305) to pull additional heat from the modulators 304. The heat pipes 510 disposed around a circumference of the modulator rotor subassembly 320 can be shaped in a manner to maximize surface area for each individual heat pipe 502.

FIG. 23 depicts an implementation of the axial flux coaxial magnetic gear 300 as a hub-type assembly with a hub housing 550 and modulators 304 being contained within the modulator subassembly 320. The modulators 304 can maintain a distance from the permanent magnets 307 on the second rotor 306, which is mechanically coupled with second rotor shaft 311. Heat pipes 530 can be included within a rotating body subassembly 552 (e.g., second rotor 306, second rotor shaft 311, etc.). Each individual heat pipe 531 can have a heat pipe section 533 that extends into the rotor subassembly 552. The heat pipe section 533 can extend into the back iron of the second rotor 306 (e.g., the permanent magnet rotor assembly), or can extend into a custom magnet with heat pipe 531 making physical contact with a magnet 532.

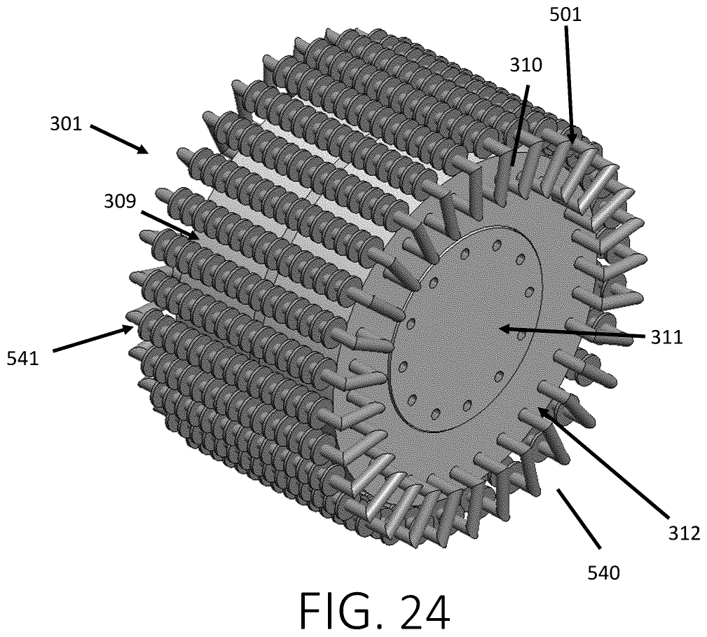

FIG. 24 illustrates another example of axial flux coaxial magnetic gear 300 mentioned above having a first rotor 301 (e.g., a high-speed rotor assembly) and a second rotor 306 (e.g., low-speed rotor assembly) inside stationary housings 309 and 312, respectively, being connected by surface area increasing heat pipes 540 wherein each individual heat pipe 541 has disc or bell-like shapes to increase total surface area allowing additional convection cooling.

In the foregoing specification, the systems and processes have been described with reference to specific implementations thereof. It will, however, be evident that various modifications and changes may be made thereto without departing from the broader spirit and scope of the implementations disclosed herein. The specification and drawings are, accordingly, to be regarded in an illustrative rather than restrictive sense.

Indeed, although the systems and processes have been disclosed in the context of certain implementations and examples, it will be understood by those skilled in the art that the various implementations of the systems and processes extend beyond the specifically disclosed implementations to other alternative implementations and/or uses of the systems and processes and obvious modifications and equivalents thereof. In addition, while several variations of the implementations of the systems and processes have been shown and described in detail, other modifications, which are within the scope of this disclosure, will be readily apparent to those of skill in the art based upon this disclosure. It is also contemplated that various combinations or sub-combinations of the specific features and implementations of the implementations may be made and still fall within the scope of the disclosure. It should be understood that various features and implementations of the disclosed implementations can be combined with, or substituted for, one another in order to form varying modes of the implementations of the disclosed systems and processes. Any methods disclosed herein need not be performed in the order recited. Thus, it is intended that the scope of the systems and processes herein disclosed should not be limited by the particular implementations described above.

It will be appreciated that the systems and methods of the disclosure each have several innovative implementations, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate implementations also may be implemented in combination in a single implementation. Conversely, various features that are described in the context of a single implementation also may be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every implementation.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain implementations include, while other implementations do not include, certain features, elements and/or states. Thus, such conditional language is not generally intended to imply that features, elements and/or states are in any way required for one or more implementations.

While certain implementations have been described, these implementations have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative implementations may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various implementations described above can be combined to provide further implementations. The accompanying claims and their equivalents are intended to cover such forms or modifications as would fall within the scope and spirit of the disclosure.

Several illustrative examples of a cooling system for an electric machine and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed devices, systems, and methods. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages, and features of several devices, systems, and methods have been described herein. Not all, or any such advantages are necessarily achieved in accordance with any particular example of the devices, systems, and methods disclosed herein. No aspects of this disclosure are essential or indispensable. In many examples, the devices, systems, and methods may be configured differently than illustrated in the figures or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain implementations require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the implementations shown herein but are to be accorded a fair interpretation consistent with this disclosure, the principles, and the novel features disclosed herein.

1. An electric machine comprising:
an inner rotor comprising a plurality of magnets;
a modulator comprising a plurality of flow paths and at least partially surrounding the inner rotor; and
a stator at least partially surrounding the modulator;
wherein, during operation of the electric machine, the plurality of flow paths conveys a flow of a cooling liquid through at least one of the inner rotor, the modulator, or the stator.

2. The electric machine of claim 1, wherein the modulator comprises a plurality of ferromagnetic pieces and a holder.

3. The electric machine of claim 2, wherein the plurality of flow paths are located within the plurality of ferromagnetic pieces.

4. The electric machine of claim 2, wherein the plurality of flow paths are located within the holder.

5. The electric machine of claim 1, wherein the plurality of flow paths are parallel to an axis of operation.

6. The electric machine of claim 1, wherein the plurality of flow paths comprise a plurality of outlets within the electric machine.

7. The electric machine of claim 1, wherein the plurality of flow paths comprise a plurality of outward outlets configured to deliver flow to a first gap radially outward of the modulator or a plurality of inward outlets configured to deliver flow to a second gap radially inward of the modulator.

8. The electric machine of claim 7, wherein the plurality of flow paths comprises a plurality of outward outlets configured to deliver flow to a first gap radially outward of the modulator and a plurality of inward outlets configured to deliver flow to a second gap radially inward of the modulator, and wherein the plurality of outward outlets are offset from the plurality of inward outlets.

9. The electric machine of claim 1, further comprising a first set of distribution paths that extend radially outward and are configured to facilitate the flow of the cooling liquid to the plurality of flow paths.

10. The electric machine of claim 9, wherein the inner rotor further comprises a hollow shaft, and wherein the hollow shaft is configured to facilitate the flow of the cooling liquid to the first set of distribution paths.

11. An electric machine comprising:
an inner rotor;
a modulator that at least partially surrounds the inner rotor; and
an outer component set that at least partially surrounds the modulator, the outer component set comprising:
a stator comprising a plurality of slots facing the modulator;
a plurality of windings located within the plurality of slots;
a plurality of magnets located on an inner side of the stator; and
a plurality of slot gaps at least partially defined by the plurality of magnets, the plurality of slots, and the plurality of windings.

12. The electric machine of claim 11, wherein the plurality of windings comprise a winding coating.

13. The electric machine of claim 11, wherein the plurality of slot gaps comprise a slot gap coating.

14. The electric machine of claim 11, wherein a fluid within the plurality of slot gaps directly contacts the plurality of magnets and the plurality of windings.

15. The electric machine of claim 11, further comprising a first set of distribution paths that extend radially outward and are configured to deliver a flow to the plurality of slot gaps.

16. The electric machine of claim 11, wherein the modulator comprises a plurality of flow paths.

17. The electric machine of claim 16, wherein the plurality of flow paths comprise a plurality of outlets.

18. The electric machine of claim 17, wherein the plurality of outlets facilitate flow to a first gap between the modulator and the inner rotor or to a second gap between the modulator and the outer component set.

19. An electric machine comprising:
an inner rotor; and
a stator that at least partially surrounds the inner rotor, the stator comprising:
a plurality of slots spaced around an inner circumference of the stator; and
a plurality of windings located within the plurality of slots;
wherein at least one winding of the plurality of windings comprises a fluid passage.

20. The electric machine of claim 19, wherein the at least one winding is a hollow winding, and wherein the fluid passage comprises a plurality of fluid passageways located within the hollow winding.

21-48. (canceled)
